(19) United States
(12) Patent Application Publication
(10) Pub. No.: US 2026/0033221 A1
(43) Pub. Date: Jan. 29, 2026

(54) LIGHT-EMITTING SUBSTRATE, DISPLAY PANEL, AND MANUFACTURING METHOD THEREOF

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/267,566

(22) Filed: Jul. 13, 2025

(30) Foreign Application Priority Data
Jul. 23, 2024 (CN) 202410996050.3

(51) Int. Cl. H10K 59/80; H10K 59/12; H10K 59/123

(52) U.S. Cl. CPC H10K 59/878; H10K 59/1201; H10K 59/123

(57) ABSTRACT

The present application provides a light-emitting substrate, a display panel, and a manufacturing method thereof. The light-emitting substrate includes a glass substrate, and light-emitting units and bonding portions respectively arranged on two sides of the glass substrate. The light-emitting substrate includes anode electrodes, light-emitting layers, and cathode electrodes stacked in sequence. Each of the anode electrodes covers a glass through-hole, and includes a light-condensing layer, a first reflective layer, a first transparent conductive layer, a second reflective layer, and a second transparent conductive layer, which are stacked in sequence. The light-condensing layer may concentrate lasers located in a region of the glass through-hole, the first reflective layer may reflect the lasers, and the lasers are configured to form the glass through-hole. Each of the bonding portions passes through a glass through-hole to be in contact with and electrically connected to an anode electrode or a cathode electrode.

### CROSS REFERENCE TO RELATED APPLICATIONS

The present disclosure claims priority to Chinese patent application No. 202410996050.3 filed on Jul. 23, 2024, the entire contents of which are incorporated herein by reference.

### TECHNICAL FIELD

The present disclosure relates to the field of display technologies, and in particular to a light-emitting substrate, a display panel, and a manufacturing method thereof.

### BACKGROUND

A single-crystal silicon driving backplane is a driving substrate formed with semiconductor components manufactured by complementary metal oxide semiconductor (CMOS) processes as driving units. Compared with a conventional active-matrix organic light-emitting diode (AMOLED) panel using amorphous silicon, microcrystalline silicon, or low-temperature polycrystalline silicon thin-film transistors as a backplane, the single-crystal silicon driving backplane has higher carrier mobility. Therefore, a silicon-based organic light-emitting diode (OLED) display panel is currently a type of display panel with the best performance among products applied in the augmented reality (AR)/virtual reality (VR) field.

At present, the silicon-based OLED display panel integrates traditional externally bonded display chips into a silicon-based driving backplane. A manufacturing method thereof involves evaporating and fabricating OLED light-emitting components on a silicon-based driving substrate. Specifically, an anode is first deposited, then a pixel definition layer is fabricated, followed by sequentially depositing an organic light-emitting layer and a cathode. In this way, smaller-sized pixel units can be fabricated, achieving a display fineness beyond the retinal level, with advantages such as high resolution, high integration, low power consumption, small size, and light weight.

However, directly evaporating and fabricating OLED light-emitting components on the silicon-based driving substrate may easily affect a silicon-based driving circuit, leading to damage to the circuit and causing the circuit to be unusable, thereby increasing costs.

### SUMMARY OF THE DISCLOSURE

In order to solve the problems mentioned above, a first technical solution provided by the present disclosure is a light-emitting substrate. The light-emitting substrate includes a glass substrate, a plurality of light-emitting units, and a plurality of bonding portions. The glass substrate includes a first side and a second side opposite to each other, and the glass substrate has a plurality of glass through-holes defined therein. The plurality of light-emitting units are arranged on the first side of the glass substrate, each including an anode electrode, a light-emitting layer, and a cathode electrode stacked in sequence along a direction away from the glass substrate. The anode electrode covers a corresponding one of the glass through-holes, and includes a light-condensing layer, a first reflective layer, a first transparent conductive layer, a second reflective layer, and a second transparent conductive layer, which are stacked in sequence along the direction away from the glass substrate. The light-condensing layer is configured to concentrate lasers located in a region of the corresponding one of the glass through-holes on the second side, the first reflective layer is configured to reflect the lasers, and the lasers are configured to form the corresponding one of the glass through-holes. The plurality of bonding portions is arranged on the second side of the glass substrate, each passing through a corresponding one of the glass through-holes to be in contact with and electrically connected to the anode electrode or the cathode electrode. The bonding portions are configured for alignment bonding with a driving substrate.

In order to solve the problems mentioned above, a second technical solution provided by the present disclosure is a manufacturing method of a display panel. The manufacturing method of the display panel includes steps of: manufacturing a light-emitting substrate, including: providing a glass substrate; forming a plurality of anode electrodes on a first side of the glass substrate, including: depositing a light-condensing layer, a first reflective layer, a first transparent conductive layer, a second reflective layer, and a second transparent conductive layer sequentially, and performing a patterning process to form the anode electrodes; depositing a plurality of light-emitting layers and a plurality of cathode electrodes sequentially on the anode electrodes to form a plurality of light-emitting units; forming a plurality of glass through-holes on a second side of the glass substrate by laser ablation, a part of the glass through-holes being located within orthographic projections of the anode electrodes projected on the glass substrate; the light-condensing layer being configured to concentrate lasers, and the first reflective layer being configured to reflect the lasers; depositing a metal layer on the second side of the glass substrate, enabling the metal layer to fill within the glass through-holes and to be in contact with and electrically connected to the anode electrodes and the cathode electrodes respectively, and performing a patterning process on the metal layer to form a plurality of bonding portions; manufacturing a driving substrate, including: providing a silicon substrate; and fabricating a driving circuit layer and a plurality of driving electrodes sequentially on the silicon substrate, the driving electrodes being electrically coupled to the driving circuit layer; and aligning and bonding the bonding portions of the light-emitting substrate with the driving electrodes of the driving substrate.

In order to solve the problems mentioned above, a third technical solution provided by the present disclosure is a display panel. The display panel includes a light-emitting substrate according to any one of embodiments mentioned above, and a driving substrate. The driving substrate is aligned and bonded with the light-emitting substrate for driving the light-emitting substrate to emit light.

### BRIEF DESCRIPTION OF THE DRAWINGS

In order to more clearly illustrate the technical solutions in the embodiments of the present disclosure, the drawings needed to be used in the embodiments are briefly introduced below. Obviously, the drawings in the following description are only some embodiments of the present disclosure. For those skilled in the art, other drawings may also be obtained according to these drawings without any creative efforts.

FIG. 1 is a schematic structural view of a display panel according to some embodiments of the present disclosure.

FIG. 2 is a first schematic structural view of a light-emitting substrate according to some embodiments of the present disclosure.

FIG. 3 is a schematic structural view of a stacked anode electrode shown in FIG. 2.

FIG. 4 is a second schematic structural view of a light-emitting substrate according to some embodiments of the present disclosure.

FIG. 5 is a planar schematic structural view of a thermal insulation layer of the light-emitting substrate shown in FIG. 4.

FIG. 6 is a third schematic structural view of a light-emitting substrate according to some embodiments of the present disclosure.

FIG. 7 is a planar schematic structural view of a thermal insulation layer of the light-emitting substrate shown in FIG. 6.

FIG. 8 is a fourth schematic structural view of a light-emitting substrate according to some embodiments of the present disclosure.

FIG. 9 is a schematic flow chart of a manufacturing method of a display panel according to some embodiments of the present disclosure.

FIG. 10 is a first schematic flow chart of block S10 shown in FIG. 9.

FIG. 11 is a schematic process chart of a light-emitting substrate shown in FIG. 10.

FIG. 12 is a second schematic flow chart of block S10 shown in FIG. 9.

FIG. 13 is a schematic process chart of a light-emitting substrate shown in FIG. 12.

FIG. 14 is a schematic flow chart of block S20 shown in FIG. 9.

FIG. 15 is a schematic process chart of a driving substrate shown in FIG. 14.

### REFERENCE LABELS OF THE DRAWINGS

100 display panel; 10 light-emitting substrate; 11 glass substrate; 111 glass through-hole; 12 anode electrode; 121 light-condensing layer; 122 first reflective layer; 123 first transparent conductive layer; 124 second reflective layer; 125 second transparent conductive layer; 13 pixel definition layer; 131 pixel opening; 14 light-emitting layer; 15 cathode electrode; 16 bonding portion; 17 encapsulating layer; 18 thermal insulation layer; 181 hollowed-out portion; 182 overlapping portion; 183 excess portion; 20 driving substrate; 21 silicon substrate; 22 driving circuit layer; 23 driving electrode; 231 anode driving electrode; 232 cathode driving electrode; 24 insulating protective layer; 241 via-hole.
L light-emitting unit; L1 first light-emitting unit; L2 second light-emitting unit; L3 third light-emitting unit; W1 first preset value; W2 second preset value.

### DETAILED DESCRIPTION

The solutions in the embodiments of the present disclosure are described in detail below in conjunction with the accompanying drawings.

In the following description, for illustrative rather than limitation, specific details such as specific system structures, interfaces, technologies, etc., are presented to facilitate a thorough understanding of the present disclosure.

The technical solutions in the embodiments of the present disclosure are described clearly and completely below in conjunction with the accompanying drawings in the embodiments of the present disclosure. Obviously, the mentioned embodiments are merely some, not all of the embodiments of the present disclosure. Based on the embodiments in the present disclosure, all other embodiments obtained by those skilled in the art without creative work fall within the scope of protection of the present disclosure.

In the present disclosure, the terms “first”, “second”, and “third” are for descriptive purposes only, and should not be construed as indicating or implying relative importance or implying the number of technical features indicated. Thus, features defining with the terms “first”, “second”, and “third” may explicitly or implicitly include at least one of these features. In the description of the present disclosure, the term “plurality” means at least two, such as two, three, etc., unless otherwise expressly and specifically qualified. All directional indications (such as up, down, left, right, front, back . . . ) in the embodiments of the present disclosure are only used to explain the relative positional relationship, motion states, and etc. between various components in specific postures (as shown in the accompanying drawings). If the specific postures change, the directional indications will change accordingly. In additions, the terms “comprise” and “include”, as well as any variations thereof, are intended to cover non-exclusive inclusions. For example, a process, method, system, product, or device that contains a series of steps or units is not limited to listed steps or units, but may optionally include a step or unit that is not listed, or may optionally include other steps or units that are inherent to the process, method, product, or device.

The term “embodiment” mentioned in the specification means that particular features, structures, or characteristics described in conjunction with the embodiments may be included in at least one embodiment of the present disclosure. This term appearing in various positions in the specification does not necessarily refer to the same embodiment, nor is it an independent or alternative embodiment mutually exclusive with other embodiments. Those skilled in the art explicitly or implicitly understand that the embodiments described in the specification may be combined with other embodiments.

The present disclosure will be illustrated in detail below in conjunction with the accompanying drawings and embodiments.

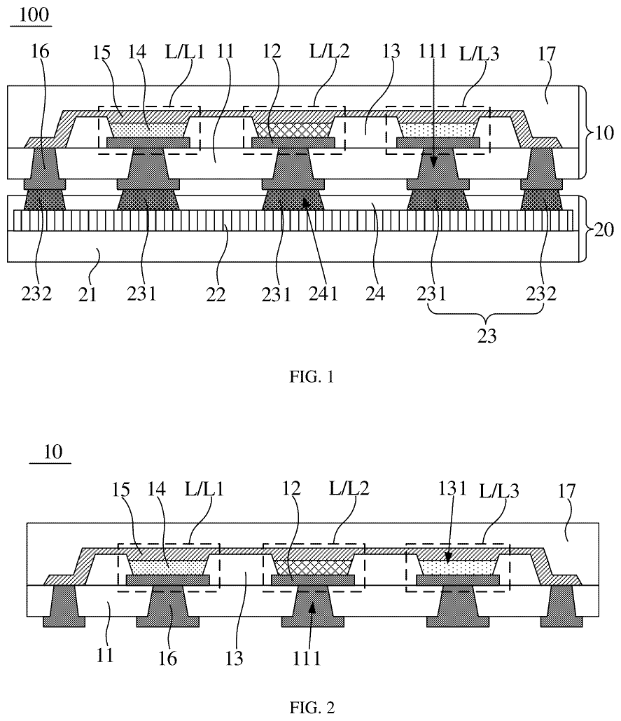

As shown in FIG. 1, FIG. 1 is a schematic structural view of a display panel according to some embodiments of the present disclosure. A display panel 100 is provided in some embodiments. The display panel 100 includes a light-emitting substrate 10 and a driving substrate 20. The light-emitting substrate 10 is aligned and bonded with the driving substrate 20, enabling the driving substrate 20 to drive the light-emitting substrate 10 to emit light, thereby an image is displayed.

The driving substrate 20 includes a silicon substrate 21, a driving circuit layer 22, a bonding electrode layer, and an insulating protective layer 24. The silicon substrate 21, the driving circuit layer 22, and the insulating protective layer 24 are stacked in sequence. In some embodiments, the silicon substrate 21 may be configured as a single-crystal silicon substrate.

The driving circuit layer 22 includes multiple pixel driving circuit units (not shown), each pixel driving circuit unit including a driving component. In some embodiments, a complementary metal oxide semiconductor (CMOS) component may be used as the driving component to form the pixel driving circuit unit, thereby a light-emitting unit L in the light-emitting substrate 10 is driven to emit light.

The bonding electrode layer is electrically coupled to the driving circuit layer 22. The bonding electrode layer includes multiple driving electrodes 23, and the driving electrodes 23 are electrically connected to the pixel driving circuit units, enabling driving signals to be transmitted from the pixel driving circuit units to the driving electrodes 23, and then transmitted to the light-emitting substrate 10 through the driving electrodes 23. The driving electrodes 23 include multiple anode driving electrodes 231 and multiple cathode driving electrodes 232. The cathode driving electrodes 232 are located in an edge region of the bonding electrode layer and are configured to be electrically coupled with cathode electrodes 15 in the light-emitting substrate 10. The anode driving electrodes 231 are configured to be electrically coupled with anode electrodes 12 of light-emitting units L. The anode driving electrodes 231 are located in a main region of the bonding electrode layer and are arranged in a one-to-one correspondence with the light-emitting units L in the light-emitting substrate 10, facilitating the alignment bonding of the driving substrate 20 with the light-emitting substrate 10.

The insulating protective layer 24 is arranged on a side of the driving circuit layer 22 away from the silicon substrate 21, and has multiple via-holes 241 defined therein. The driving electrodes 23 pass through the insulating protective layer 24 and are electrically connected to the pixel driving circuit units, and portions of the driving electrodes 23 are exposed to be configured for alignment bonding with the light-emitting substrate 10. The insulating protective layer 24 may include an organic insulating layer and/or an inorganic insulating layer. The insulating protective layer 24 may be configured as an inorganic insulating layer, and the inorganic insulating layer may be an inorganic insulating material such as silicon dioxide, silicon nitride, or silicon oxynitride.

The light-emitting substrate 10 includes a glass substrate 11 and light-emitting units L and bonding portions 16 respectively arranged on two opposite sides of the glass substrate 11. The glass substrate 11 includes a first side and a second side opposite to each other. An electrode layer is arranged on the first side of the glass substrate 11, including multiple anode electrodes 12.

A pixel definition layer 13 is arranged on a side of the anode electrodes 12 away from the glass substrate 11. The pixel definition layer 13 is defined with multiple pixel openings 131 through a patterning process. The pixel openings 131 correspond one-to-one with the light-emitting units L and overlap with the anode electrodes 12 along a direction perpendicular to the glass substrate 11, so as to expose the anode electrodes 12.

A plurality of light-emitting layers 14 is arranged within the pixel openings 131 and in contact with the anode electrodes 12. A plurality of cathode electrodes 15 is arranged on sides of the light-emitting layers 14 away from the glass substrate 11 and in contact with the light-emitting layers 14. In this way, an anode electrode 12, a light-emitting layer 14, and a cathode electrode 15 within each pixel opening 131 form a light-emitting unit L. In some embodiments, the light-emitting unit L may include a first light-emitting unit L1, a second light-emitting unit L2, and a third light-emitting unit L3 with different light-emitting colors, such as a red light-emitting unit, a green light-emitting unit, and a blue light-emitting unit, to achieve color display. A light-emitting color of the light-emitting unit L is determined by a light-emitting color of the light-emitting layer 14. Alternatively, in other embodiments, the light-emitting unit L may also be a light-emitting unit L with the same color, such as white, red, green, blue, or other colors, which may be specifically set according to actual requirements. For example, when the light-emitting color of the light-emitting unit L is white, grayscale display may be achieved by controlling a brightness of the light-emitting unit L, or color display may be achieved by providing a color filter layer above the light-emitting unit L.

The bonding portions 16 are arranged on the second side of the glass substrate 11. The glass substrate 11 has multiple glass through-holes 111 defined therein. The bonding portions 16 pass through the glass through-holes 111 to be in contact with and electrically connected to the corresponding anode electrodes 12 or the cathode electrode 15. The cathode electrode 15 extends to an edge position of the glass substrate 11, and a bonding portion 16 at the edge position passes through a corresponding glass through-hole 111 to be in contact with and electrically connected to the cathode electrode 15. The bonding portions 16 are aligned and bonded with the driving electrodes 23 of the driving substrate 20, enabling the anode electrodes 12 and the cathode electrode 15 of the light-emitting units L to be respectively electrically coupled with the anode driving electrodes 231 and the cathode driving electrodes 232 through the corresponding bonding portion 16, so that the driving signal of the driving substrate 20 may be transmitted to the anode electrodes 12 and the cathode electrode 15 of the light-emitting units L through the bonding portions 16, thereby driving the light-emitting units L to emit light and achieving image display.

Through the above configuration, the light-emitting substrate 10 and the driving substrate 20 are electrically coupled by bonding. This allows the light-emitting substrate 10 to be manufactured separately and then bonded with the driving substrate 20, eliminating the need to manufacture the light-emitting units L directly on the driving substrate 20. This avoids the problem of reduced product yield caused by damage to the pixel driving circuit when manufacturing the light-emitting units L directly on the driving substrate 20. Moreover, by using the glass substrate 11 as a base substrate of the light-emitting substrate 10, compared with a silicon-based substrate, since the glass substrate 11 has better insulation performance, there is no need to fabricate an oxide insulation layer on walls of the glass through-holes 111, nor is there a need for special thin wafer handling technology, which may reduce costs. Additionally, the glass substrate 11 is cheaper than the silicon-based substrate, further reducing costs. Meanwhile, due to the good insulation performance of the glass substrate 11, it is less likely to generate electromagnetic coupling effects during signal transmission. This may effectively reduce problems such as signal insertion loss and crosstalk, ensuring the integrity of the signals. Furthermore, forming the light-emitting units L on the glass substrate 11 facilitates the realization of a large-sized light-emitting substrate 10.

However, through further research, the inventor of the present disclosure has found that during a process of forming the glass through-holes 111 in the glass substrate 11, since the anode electrodes 12 covers the glass through-holes 111, when lasers irradiate regions of the glass through-holes 111, the energy of the lasers is high, which is extremely easy to damage a structure of the light-emitting layer 14 and the cathode electrode 15 above the anode electrodes 12, resulting in the failure of the light-emitting units L and a decrease in the product yield. In order to solve these technical problems, the present disclosure provides a light-emitting substrate 10 shown in the following embodiments. The specific structure of the light-emitting substrate 10 is described in detail below.

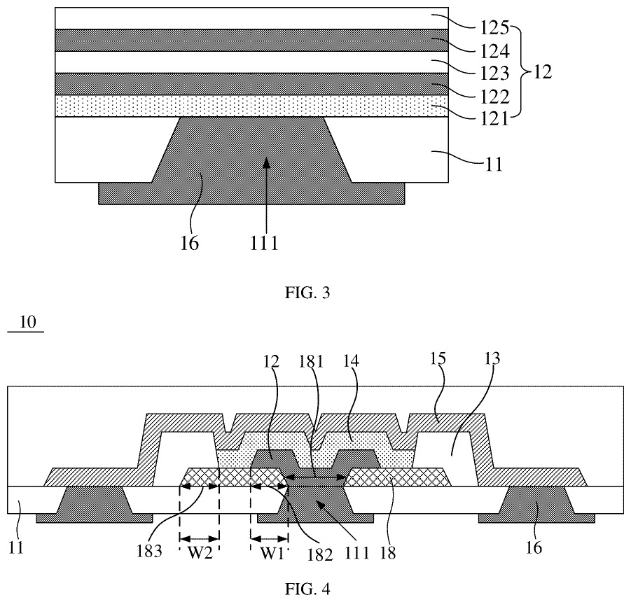

As shown in FIG. 2 and FIG. 3, FIG. 2 is a schematic structural view of a light-emitting substrate according to a first embodiment of the present disclosure, and FIG. 3 is a schematic structural view of a stacked anode electrode shown in FIG. 2. A light-emitting substrate 10 is provided in some embodiments. The light-emitting substrate 10 includes a glass substrate 11, multiple light-emitting units L, and multiple bonding portions 16. The structures and functions of the glass substrate 11, the light-emitting units L, and the bonding portions 16 are the same as or similar to the structures and functions of the glass substrate 11, the light-emitting units L, and the bonding portions 16 in the embodiments shown in FIG. 1, and can achieve the same technical effects. For details, please refer to the above introduction, and will not be repeated here.

In some embodiments, as shown in FIG. 3, the anode electrode 12 of each light-emitting unit L includes a light-condensing layer 121, a first reflective layer 122, a first transparent conductive layer 123, a second reflective layer 124, and a second transparent conductive layer 125, which are stacked in sequence along a direction away from the glass substrate 11. When the lasers irradiate the positions of the glass through-holes 111 during forming the glass through-holes 111, the light-condensing layer 121 closest to the glass substrate 11 may be configured to concentrate the lasers located in a region of a corresponding glass through-hole 111 on the second side of the glass substrate 11, so that the laser energy is concentrated in the region of the corresponding glass through-hole 111, thereby improving the utilization rate of the lasers. Furthermore, after the lasers pass through the light-condensing layer 121, the first reflective layer 122 may be configured to reflect the lasers back to the glass substrate 11, so that the lasers act on the region of the corresponding glass through-hole 111 of the glass substrate 11 again, further improving the utilization rate of the lasers for forming the glass through-holes 111. Moreover, the first reflective layer 122 prevents the lasers from continuing to irradiate above the anode electrode 12, so as to protect the light-emitting layer 14 and the cathode electrode 15 above the anode electrode 12, avoiding the problem that the lasers damage the light-emitting layer 14 and/or the cathode electrode 15, resulting in the failure of the light-emitting unit L, thereby further improving the product yield.

The glass through-hole 111 is located within a region of an orthographic projection of the anode electrode 12 projected on the glass substrate 11, so that the bonding portion 16 may pass through the glass through-hole 111 and accurately align and be in contact with the anode electrode 12 to form an electrical connection. A material of the light-condensing layer 121 may include copper (Cu), aluminum (Al), or molybdenum (Mo), which not only has good electrical conductivity, but also can absorb lasers. By taking advantage of its absorption characteristics of the lasers, the light-condensing layer 121 may absorb the lasers, endowing the light-condensing layer 121 with the function of concentrating the lasers. Therefore, when laser drilling is performed on the glass substrate 11, through the concentrating effect of the light-condensing layer 121, more laser energy may be concentrated in regions of the glass substrate 11 where holes need to be formed, improving the efficiency of laser drilling.

Materials of the first reflective layer 122 and the second reflective layer 124 may include silver (Ag) or aluminum (Al), or other metal materials with good reflectivity and conductivity. In this way, the first reflective layer 122 may be configured to reflect the lasers, and the second reflective layer 124 may reflect a light from the light-emitting layer 14. Thus, when laser drilling is performed on the glass substrate 11, the lasers passing through the light-condensing layer 121 may be reflected back to the glass substrate 11 by the first reflective layer 122, improving the efficiency of laser drilling. Moreover, the lasers are also prevented from damaging the light-emitting layer 14 and other structures above the anode electrode 12 through the anode electrode 12. The second reflective layer 124 may be configured to reflect the light from the light-emitting layer 14, improving the luminous efficiency of the light-emitting layer 14 and enhancing a display brightness of the display panel 100.

Furthermore, since the materials of the first reflective layer 122 and the second reflective layer 124 are Ag or Al, which are relatively chemically active and are prone to be oxidized and lose their reflective properties. In order to prevent the first reflective layer 122 and the second reflective layer 124 from being oxidized when exposed, the first transparent conductive layer 123 is arranged on a side surface of the first reflective layer 122 away from the glass substrate 11, and the second transparent conductive layer 125 is arranged on a side surface of the second reflective layer 124 away from the glass substrate 11, respectively covering the first reflective layer 122 and the second reflective layer 124. In this way, passivation layers are formed on an upper surface of the first reflective layer 122 and an upper surface of the second reflective layer 124 respectively, thus avoiding the first reflective layer 122 and the second reflective layer 124 from being oxidized and losing their reflective properties. Meanwhile, by arranging the second transparent conductive layer 125, the light from the light-emitting layer 14 may pass through the second transparent conductive layer 125 and be reflected back to pixel regions by the second reflective layer 124, thereby improving the luminous brightness. Materials of the first transparent conductive layer 123 and the second transparent conductive layer 125 may be metal oxides such as indium tin oxide (ITO), indium zinc oxide (IZO), indium gallium zinc oxide (IGZO), to serve as a passivation layer to protect the first reflective layer 122 and the second reflective layer 124.

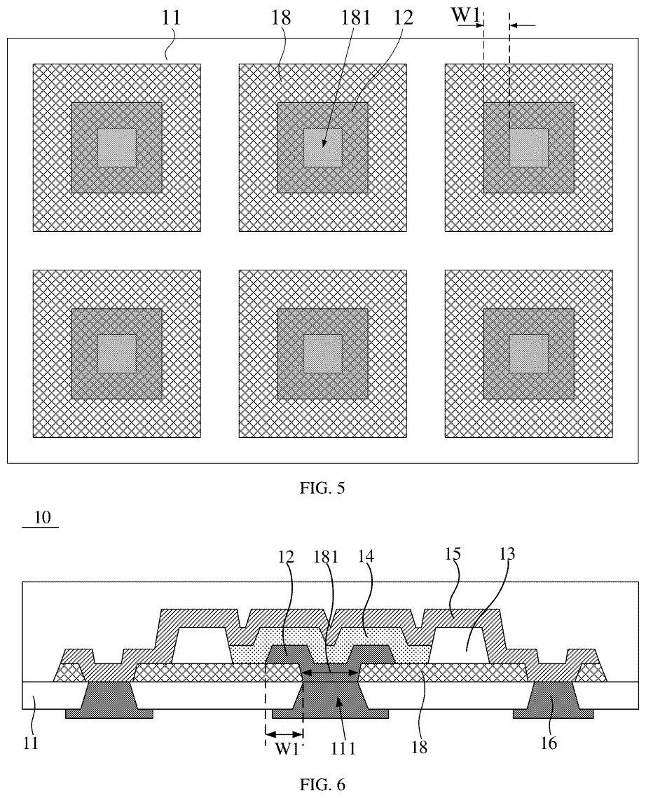

As shown in FIG. 4 and FIG. 5, FIG. 4 is a schematic structural view of a light-emitting substrate according to a second embodiment of the present disclosure, and FIG. 5 is a planar schematic structural view of a thermal insulation layer according to the second embodiment of the present disclosure. Furthermore, due to reasons such as the precision of the equipment and alignment error, when the glass through-holes 111 are formed in the glass substrate 11, the laser spots on the glass substrate 11 may likely to shift. Therefore, it is easy to cause the problem that the light-emitting layer 14 and the cathode electrode 15 are damaged by the lasers. In order to solve this technical problem, a light-emitting substrate 10 is provided in some embodiments. The light-emitting substrate 10 further includes a thermal insulation layer 18. The thermal insulation layer 18 is located between the anode electrodes 12 and the pixel definition layer 13 along the direction parallel to the glass substrate 11. The thermal insulation layer 18 has multiple hollowed-out portions 181 defined therein. Each anode electrode 12 is located in a corresponding hollowed-out portion 181 and extends out of the corresponding hollowed-out portion 181, partially overlapping with the thermal insulation layer 18. An overlapping portion 182 of the thermal insulation layer 18 is located between the anode electrode 12 and the glass substrate 11. A width of the overlapping portion 182 is not less than a first preset value W1. The thermal insulation layer 18 is configured to block the energy of the lasers. The first preset value W1 is a precision of a manufacturing process.

By arranging the thermal insulation layer 18 between the anode electrodes 12 and the glass substrate 11, when the laser spots on the glass substrate 11 shift during forming the glass through-holes 111 in the glass substrate 11, the presence of the thermal insulation layer 18 may block the energy of the lasers, thereby avoiding the problem that the light-emitting layer 14 and/or the cathode electrode 15 is damaged due to the laser shift. Meanwhile, by making the thermal insulation layer 18 overlap with an edge of the anode electrode 12 and having the overlapping portion 182 located on a side of the anode electrode 12 close to the glass substrate 11, the thermal insulation layer 18 may block the laser energy around the glass through-holes 111, so as to further protect the light-emitting units L and prevent the light-emitting units L from being damaged.

The width of the overlapping portion 182 mentioned above is not less than the first preset value W1. The first preset value W1 refers to a precision of an overlapping process between the thermal insulation layer 18 and the anode electrode 12. By ensuring that the width of the overlapping portion 182 of the thermal insulation layer 18 overlapping with the anode electrode 12 is not less than the first preset value W1, the thermal insulation layer 18 and the anode electrode 12 may be in close contact without any gaps. This avoids the problem that after the laser shift, the lasers may enter an upper structure through the gaps and cause damage to the light-emitting unit L. A range of the first preset value W1 may be from 1.0 μm to 2.0 μm. For example, the first preset value W1 may be 1.0 μm, 1.2 μm, 1.4 μm, 1.5 μm, 1.6 μm, 1.8 μm, or 2.0 μm, etc. In some embodiments, the first preset value W1 may be 1.5 μm, that is, the width of the overlapping portion 182 of the thermal insulation layer 18 overlapping with the anode electrode 12 is 1.5 μm. It should be noted that the thermal insulation layer 18 surrounds a periphery of the anode electrode 12, and the overlapping portion 182 of the thermal insulation layer 18 overlapping with the anode electrode 12 is an annular. Therefore, the width of the overlapping portion 182 mentioned in the embodiments of the description refers to a radial width of the annular. Furthermore, a range of a thickness of the thermal insulation layer 18 along the direction perpendicular to the glass substrate 11 may be from 0.5 μm to 2.0 μm. For example, the thickness of the thermal insulation layer 18 may be 0.5 μm, 0.7 μm, 0.9 μm, 1.0 μm, 1.2 μm, 1.4 μm, 1.5 μm, 1.7 μm, 1.9 μm, or 2.0 μm. In some embodiments, the thickness of the thermal insulation layer 18 may be 1.0 μm to ensure that the thermal insulation layer 18 may better block the laser energy.

Furthermore, along the direction parallel to the glass substrate 11, an outer side of the thermal insulation layer 18 extends beyond an edge of the light-emitting layer 14. A width of an excess portion 183 is not less than a second preset value W2. The second preset value W2 is another precision of the manufacturing process. That is, the outer side of the thermal insulation layer 18 extends beyond the edge of the light-emitting layer 14 along the direction parallel to the glass substrate 11 to protect the light-emitting layer 14 and prevent the lasers form causing damage to the light-emitting layer 14. Meanwhile, considering the precision of an overlap manufacturing process between the thermal insulation layer 18 and the light-emitting layer 14, by making the width of the excess portion 183 of the thermal insulation layer 18 extending beyond the light-emitting layer 14 not less than the precision of the manufacturing process, it is ensured that the thermal insulation layer 18 may completely block the light-emitting layer 14 along the direction perpendicular to the glass substrate 11, so as to ensure the protective effect of the thermal insulation layer 18 on the light-emitting layer 14. The second preset value W2 may be 1.5 μm or more. In some embodiments, the second preset value W2 may be 1.5 μm, 1.6 μm, 1.7 μm, 1.8 μm, 1.9 μm, 2.0 μm, 2.2 μm, 2.4 μm, or 2.5 μm. For example, the second preset value W2 may be 1.5 μm to meet the above protection requirements for the light-emitting layer 14. The outer side of the thermal insulation layer 18 may extend beyond the anode electrode 12 by 1.5 μm or more.

Further, an orthographic projection of the hollowed-out portion 181 projected on the glass substrate 11 is coincident with the glass through-hole 111 along the direction perpendicular to the glass substrate 11. That is, a shape and size of the hollowed-out portion 181 are the same as a shape and size of the glass through-hole 111, and a central axis of the hollowed-out portion 181 and a central axis of the glass through-hole 111 are perpendicular to the glass substrate 11 and collinear with each other. In this way, the thermal insulation layer 18 may block the laser energy except for the region of the glass through-hole 111, so as to protect the light-emitting unit L in an upper layer. A material of the thermal insulation layer 18 may include a porous material or a vacuum insulation material. The porous material may use the pores contained in the material itself for thermal insulation, which may be a foam material, a fiber material, etc. The vacuum insulation material may be an aerogel material, etc., which may achieve the thermal insulation effect by blocking convection through internal vacuum, thereby blocking the laser energy. The aerogel material may be silicon aerogel, carbon aerogel, zirconian aerogel, etc.

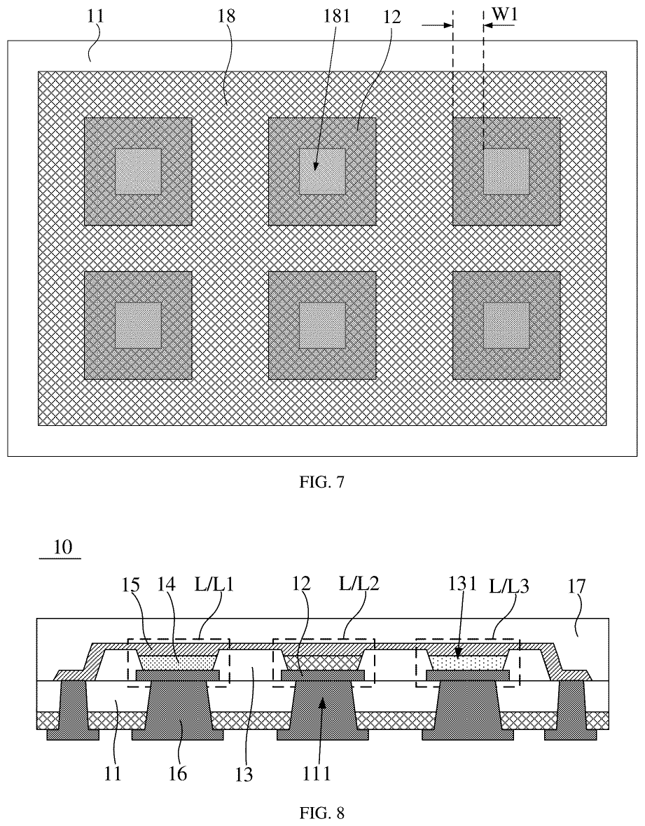

As shown in FIG. 6 and FIG. 7, FIG. 6 is a schematic structural view of a light-emitting substrate according to a third embodiment of the present disclosure, and FIG. 7 is a planar schematic structural view of a thermal insulation layer according to the third embodiment of the present disclosure. In the light-emitting substrate 10 provided by some embodiments, the thermal insulation layer 18 may fully covering the first side of the glass substrate 11 and has the hollowed-out portion 181 defined therein. The anode electrode 12 is arranged in the hollowed-out portion 181 and extends out of the hollowed-out portion 181, partially overlapping the thermal insulation layer 18. The pixel definition layer 13 is arranged on the side of the thermal insulation layer 18 away from the glass substrate 11, and the orthographic projection of the hollowed-out portion 181 projected on the glass substrate 11 is located within an orthographic projection of the pixel opening 131 projected on the glass substrate 11.

In some embodiments, the thermal insulation layer 18 fully covers the first side of the glass substrate 11, that is, the thermal insulation layer 18 is an integral structure with an entire surface, and may shield the light-emitting layer 14 along the direction perpendicular to the glass substrate 11. Therefore, there is no need to consider the problem of overlapping precision between the light-emitting layer 14 and the thermal insulation layer 18.

As shown in FIG. 8, FIG. 8 is a schematic structural view of a light-emitting substrate according to a fourth embodiment of the present disclosure. Different from the second embodiment and the third embodiment, in the light-emitting substrate 10 provided by some embodiments, the thermal insulation layer 18 is arranged on the second side of the glass substrate 11. The thermal insulation layer 18 fully covers the second side of the glass substrate 11 and has the hollowed-out portion 181 defined therein. The orthographic projection of the hollowed-out portion 181 projected on the glass substrate 11 is located within an orthographic projection of the anode electrode 12 projected on the glass substrate 11. The edge of the anode electrode 12 overlaps with the thermal insulation layer 18 along the direction perpendicular to the glass substrate 11. The hollowed-out portion 181 completely overlaps with the glass through-hole 111 along the direction perpendicular to the glass substrate 11. In this way, the thermal insulation layer 18 may shield the light-emitting layer 14 along the direction perpendicular to the glass substrate 11, to block the laser energy outside the region of the glass through-hole 111 when the glass through-hole 111 is formed in the glass substrate 11, so as to prevent the lasers from causing damage to the light-emitting unit L on the first side of the glass substrate 11. Meanwhile, by arranging the thermal insulation layer 18 on the second side of the glass substrate 11, the thermal insulation layer 18 may be fabricated either before or after the fabricating of the light-emitting unit L. Therefore, the thermal insulation layer 18 may be fabricated after a film layer structure on the first side of the glass substrate 11 is completely fabricated. The thermal insulation layer 18 only needs to be completed before the glass through-hole 111 is formed in the glass substrate 11, which makes the process of manufacturing the light-emitting substrate 10 more flexible.

Furthermore, the light-emitting substrate 10 includes an encapsulating layer 17. The encapsulating layer 17 is arranged on a side of the light-emitting unit L away from the glass substrate 11 to encapsulate the light-emitting unit L, avoiding the problem that the light-emitting unit L fails due to the invasion of external water and oxygen. The encapsulating layer 17 may include multiple inorganic encapsulating layers and multiple organic encapsulating layers stacked together to enhance the encapsulation effect.

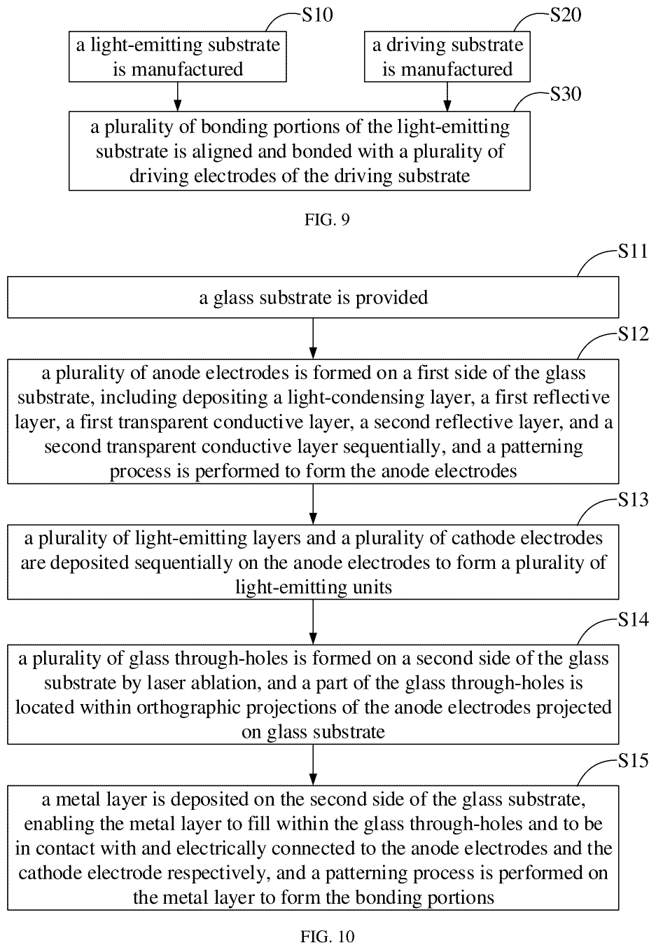

As shown in FIG. 9, FIG. 9 is a first schematic flow chart of a manufacturing method of a display panel according to some embodiments of the present disclosure. A manufacturing method of a display panel is provided by some embodiments, configured to manufacture the display panel 100 described in the above embodiments. The manufacturing method may include operations executed by the following blocks.

At block S10, a light-emitting substrate 10 is manufactured.

At block S20, a driving substrate 20 is manufactured.

At block S30, a plurality of bonding portions 16 of the light-emitting substrate 10 is aligned and bonded with a plurality of driving electrodes 23 of the driving substrate 20.

There is no sequential relationship between block S10 and block S20. That is, the light-emitting substrate 10 and the driving substrate 20 are manufactured separately. The block S10 and the block S20 may be carried out according to the production requirements, and there is no specific sequential requirement.

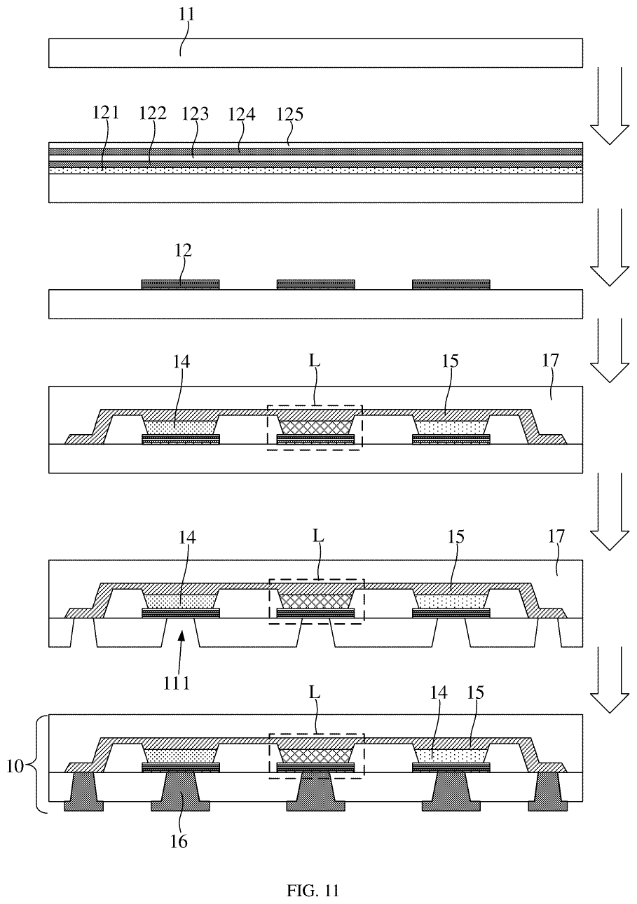

As shown in FIG. 10 and FIG. 11, FIG. 10 is a first schematic flow chart of block S10 shown in FIG. 9, and FIG. 11 is a schematic process chart of a light-emitting substrate shown in FIG. 10. The block S10 for manufacturing the light-emitting substrate 10 may include the following blocks.

At block S11, a glass substrate 11 is provided.

At block S12, a plurality of anode electrodes 12 is formed on a first side of the glass substrate 11, including depositing a light-condensing layer 121, a first reflective layer 122, a first transparent conductive layer 123, a second reflective layer 124, and a second transparent conductive layer 125 sequentially, and a patterning process is performed to form the anode electrodes 12.

At block S13, a plurality of light-emitting layers 14 and a plurality of cathode electrodes 15 are deposited sequentially on the anode electrodes 12 to form a plurality of light-emitting units L.

At block S14, a plurality of glass through-holes 111 is formed on a second side of the glass substrate 11 by laser ablation, and a part of the glass through-holes 111 is located within orthographic projections of the anode electrodes 12 projected on glass substrate 11.

At block S15, a metal layer is deposited on the second side of the glass substrate 11, enabling the metal layer to fill within the glass through-holes 111 and to be in contact with and electrically connected to the anode electrodes 12 and the cathode electrode 15 respectively, and a patterning process is performed on the metal layer to form the bonding portions 16.

At block S12, on the first side of the glass substrate 11, a material of the light-condensing layer 121, a material of the first reflective layer 122, a material of the first transparent conductive layer 123, a material of the second reflective layer 124, and a material of the second transparent conductive layer 125 are sequentially deposited. The patterning process is performed to form the light-condensing layer 121, the first reflective layer 122, the first transparent conductive layer 123, the second reflective layer 124, and the second transparent conductive layer 125, which are sequentially stacked and have a preset shape as shown in FIG. 11, so as to manufacture and form the anode electrodes 12. The material of the light-condensing layer 121, the material of the first reflective layer 122, the material of the first transparent conductive layer 123, the material of the second reflective layer 124, and the material of the second transparent conductive layer 125 are the same as or similar to the materials of each layer of the anode electrode 12 mentioned in the above embodiments, and may achieve the same technical effects. For the specific materials of each layer of the anode electrode 12, please refer to the relevant descriptions in the above embodiments.

During the patterning process performed on each layer of the anode electrode 12, an etching method is commonly used for patterning. Due to the metal characteristics of the light-condensing layer 121, the first reflective layer 122, and the second reflective layer 124, etching rates of the light-condensing layer 121, the first reflective layer 122, and the second reflective layer 124 are greater than etching rates of the first transparent conductive layer 123 and the second transparent conductive layer 125. As a result, the first transparent conductive layer 123 may collapse on the same side of the light-condensing layer 121 and the first reflective layer 122 to seal edges of the light-condensing layer 121 and the first reflective layer 122, and the second transparent conductive layer 125 may collapse on a side of the second reflective layer 124 to seal edges of the second reflective layer 124. Consequently, the first transparent conductive layer 123 coats the first reflective layer 122 and the light-condensing layer 121, and the second transparent conductive layer 125 coats the second reflective layer 124. In this way, the first transparent conductive layer 123 and the second transparent conductive layer 125 play a passivation role on the first reflective layer 122 and the second reflective layer 124 respectively, preventing the first reflective layer 122 and the second reflective layer 124 form being exposed and oxidized, which would cause them to lose their reflective properties.

At block S13, before the light-emitting layers 14 and the cathode electrodes 15 are deposited sequentially on the anode electrodes 12, the following blocks are further included: fabricating a pixel definition layer 13 on the first side of the glass substrate 11, forming a plurality of pixel openings 131 to make the pixel openings 131 to expose the anode electrodes 12. Then, evaporation may be performed through a mask to deposit and form the light-emitting layers 14 on the anode electrodes 12. Subsequently, a cathode material is evaporated to deposit and form the cathode electrodes 15 on the light-emitting layers 14 and the pixel definition layer 13, and some cathode electrodes 15 extend to edges of the glass substrate 11. Alternatively, in other embodiments, a conductive isolation structure (not shown) may be fabricated on the pixel definition layer 13, making the conductive isolation structure surround each pixel opening 131. The conductive isolation structure includes a conductive enclosure structure located on the pixel definition layer 13 and a top structure located on the conductive enclosure structure. The top structure covers the conductive enclosure structure and extends beyond the conductive enclosure structure along the direction parallel to the glass substrate 11 to form eaves structures. In this way, the conductive enclosure structure may replace the mask for evaporating the light-emitting layers 14 and a cathode layer, and the cathode electrodes 15 are in contact with the conductive enclosure structure to form a front mesh connection of the cathode electrodes 15.

At block S14, laser ablation is performed at positions on the second side of the glass substrate 11 where signal connection is required, so as to form corresponding modified regions on the glass substrate 11 corresponding to bottom regions of the anode electrodes 12 and bottom regions of the cathode electrodes 15. Then, an etching solution is used to etch the modified regions to form the glass through-holes 111, so that the anode electrodes 12 and the cathode electrodes 15 cover the corresponding glass through-holes 111 respectively. When performing the laser ablation, the light-condensing layer 121 located at the bottommost layer may be configured to concentrate the lasers in the regions where the glass through-holes 111 need to be formed, so that the laser energy is concentrated in the regions of the glass through-holes 111, thereby improving the utilization of the lasers. Furthermore, after the lasers pass through the light-condensing layer 121, the first reflection layer 122 may be configured to reflect the lasers back to the glass substrate 11, so that the lasers may act on the regions of the glass through-holes 111 of the glass substrate 11 again, further improving the utilization of the lasers for forming the glass through-holes 111. Moreover, it prevents the lasers from continuing to shoot above the anode electrodes 12, thus protecting the light-emitting layers 14 and the cathode electrodes 15 above the anode electrodes 12, avoiding the problem that the lasers damage the light-emitting layers 14 and/or the cathode electrodes 15, which may lead to the failure of the light-emitting units L, and further improving the product yield.

At block S15, after the through-holes are formed in the glass substrate 11, the metal layer is deposited on the second side of the glass substrate 11. In this way, the metal layer is deposited to fill the glass through-holes 111 and in contact with the corresponding anode electrode 12 or cathode electrode 15 to form the electrical connection. Then, a patterning process is performed on the metal layer to form the bonding portions 16. Therefore, after the bonding portions 16 of the light-emitting substrate 10 are bonded to the driving electrodes 23 of the driving substrate 20, the anode electrodes 12 of the light-emitting substrate 10 are electrically coupled with the anode driving electrodes 231 through the bonding portions 16, and the cathode electrodes 15 of the light-emitting substrate 10 are electrically coupled with the cathode driving electrodes 232 through the bonding portions 16. In this way, the light-emitting units L may receive anode driving signals and cathode driving signals of the driving substrate 20 through the bonding portions 16, thereby driving the light-emitting units L to emit light to display a image.

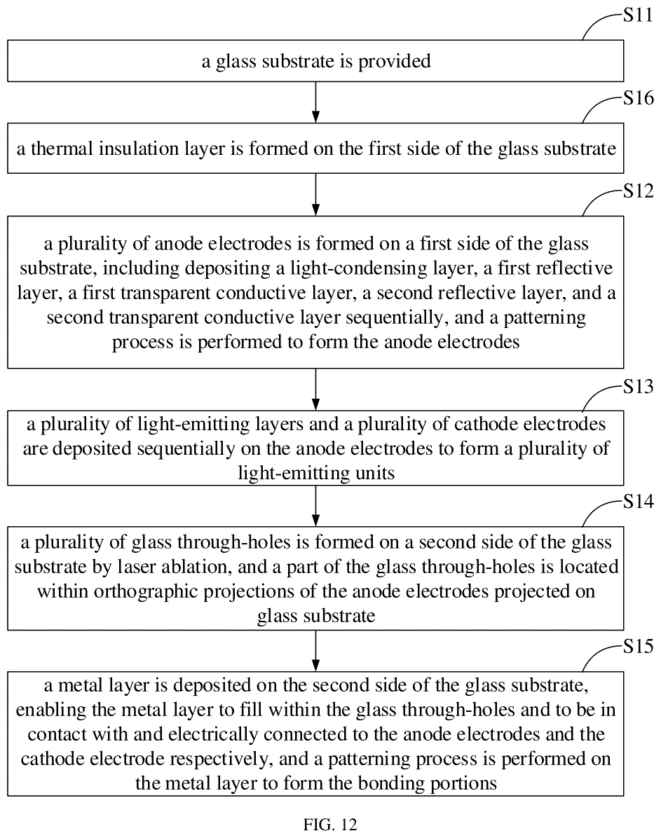

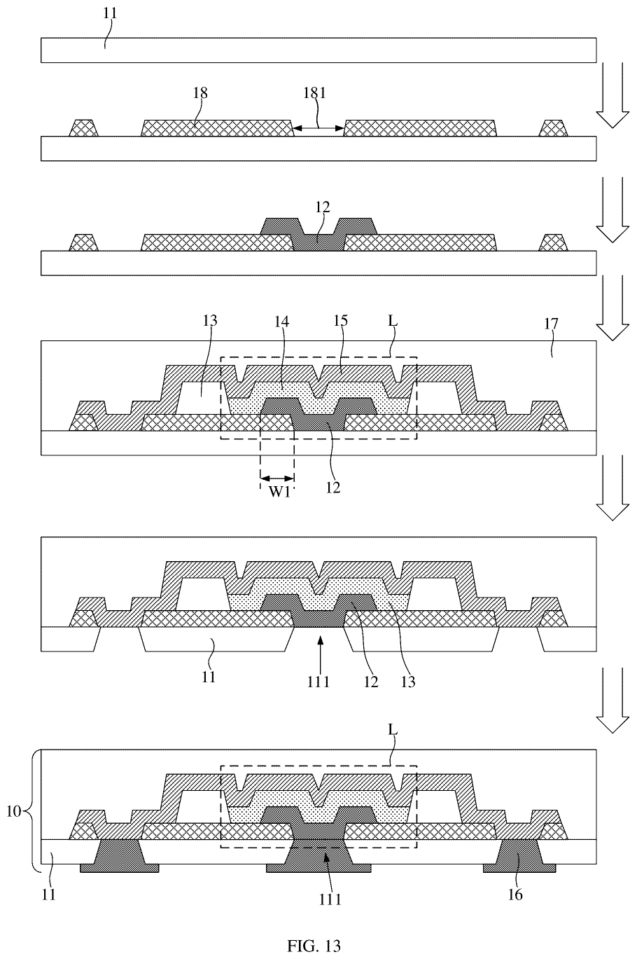

As shown in FIG. 12 and FIG. 13, FIG. 12 is a second schematic flow chart of block S10 shown in FIG. 9, and FIG. 13 is a schematic process chart of a light-emitting substrate shown in FIG. 12. In some embodiments, in block S10 for manufacturing the light-emitting substrate 10, before block S12, the following block is included.

At block S16, a thermal insulation layer 18 is formed on the first side of the glass substrate 11.

The thermal insulation layer 18 has a plurality of hollowed-out portions 181 defined therein. Each anode electrode 12 is formed in a corresponding hollowed-out portion 181 and extends to an upper surface of thermal insulation layer 18, partially overlapping with thermal insulation layer 18. A width of an overlapping portion 182 of the thermal insulation layer 18 overlapping with the anode electrode 12 is not less than a first preset value W1. The first preset value W1 is a precision of a manufacturing process. The first preset value W1 refers to a precision of an overlapping process between the thermal insulation layer 18 and the anode electrode 12. By ensuring that the width of the overlapping portion 182 of the thermal insulation layer 18 overlapping with the anode electrode 12 is not less than the first preset value W1, the thermal insulation layer 18 and the anode electrode 12 may be in close contact without any gaps. This avoids the problem that, in block S14, the lasers may shift and enter an upper structure through the gaps and cause damage to the light-emitting units L. A range of the first preset value W1 may be from 1.0 μm to 2.0 μm. A range of a thickness of the thermal insulation layer 18 along the direction perpendicular to the glass substrate 11 may be from 0.5 μm to 2.0 μm to ensure that the thermal insulation layer 18 may better block the laser energy.

A material of the thermal insulation layer 18 may include a porous material or a vacuum insulation material. The porous material may use the pores contained in the material itself for thermal insulation, which may be a foam material, a fiber material, etc. The vacuum insulation material may be an aerogel material, etc., which may achieve the thermal insulation effect by blocking convection through internal vacuum, thereby blocking the laser energy. The aerogel material may be silicon aerogel, carbon aerogel, zirconian aerogel, etc.

At block S14, the glass through-holes 111 are formed on the second side of the glass substrate 11 by laser ablation, spots of the lasers on the second side of the glass substrate 11 are coincident with the hollowed-out portion 181 along the direction perpendicular to glass substrate 11, so that the glass through-hole 111 formed by the lasers and the hollowed-out portion 181 coincide along the direction perpendicular to the glass substrate 11. In this way, the thermal insulation layer 18 may block the laser energy except for the region of the glass through-hole 111, so as to protect the light-emitting unit L in an upper layer.

In some embodiments, the thermal insulation layer 18 fully covers the first side of the glass substrate 11, that is, the thermal insulation layer 18 is an integral structure with an entire surface, and may shield the light-emitting layer 14 along the direction perpendicular to the glass substrate 11. Therefore, there is no need to consider the problem of overlapping precision between the light-emitting layer 14 and the thermal insulation layer 18. In other embodiments, a number of the thermal insulation layer 18 may more than one. An outer side of the thermal insulation layer 18 extends beyond an edge of the light-emitting layer 14 along the direction parallel to the glass substrate 11. A width of an excess portion 183 is not less than a second preset value W2. The second preset value W2 is a precision of overlap manufacturing process. It is ensured that the thermal insulation layer 18 may completely block the light-emitting layer 14 along the direction perpendicular to the glass substrate 11, so as to ensure the protective effect of the thermal insulation layer 18 on the light-emitting layer 14. The second preset value W2 may be 1.5 μm or more.

At block S16, the thermal insulation layer 18 is formed on the first side of the glass substrate 11, a patterned thermal insulation layer 18 may be formed by using a 3D printing, inkjet printing, or patterned template process. A method for forming the patterned thermal insulation layer 18 using the patterned template process may include operations as follows.

A template corresponding to a pattern of the thermal insulation layer 18 is fabricated on the first side of the glass substrate 11 through photolithography, laser etching, or other unprocessed structures.

A colloid of the thermal insulation layer 18 is painted inside the template.

Drying and curing are performed on the colloid of the thermal insulation layer 18 inside the template to form an aerogel thermal insulation layer.

The template is removed through methods such as chemical dissolution, mechanical detachment, or thermal decomposition.

In some embodiments, after fabricating and forming the light-emitting units L, block S17 may be included. At block S17, an encapsulating layer 17 is formed on a side of the light-emitting units L away from the glass substrate 11. The encapsulating layer 17 is configured to encapsulate the light-emitting units L to avoid the problem that the light-emitting units L fail due to the invasion of external water and oxygen. The encapsulating layer 17 may include multiple inorganic encapsulating layers and multiple organic encapsulating layers stacked together to enhance the encapsulation effect.

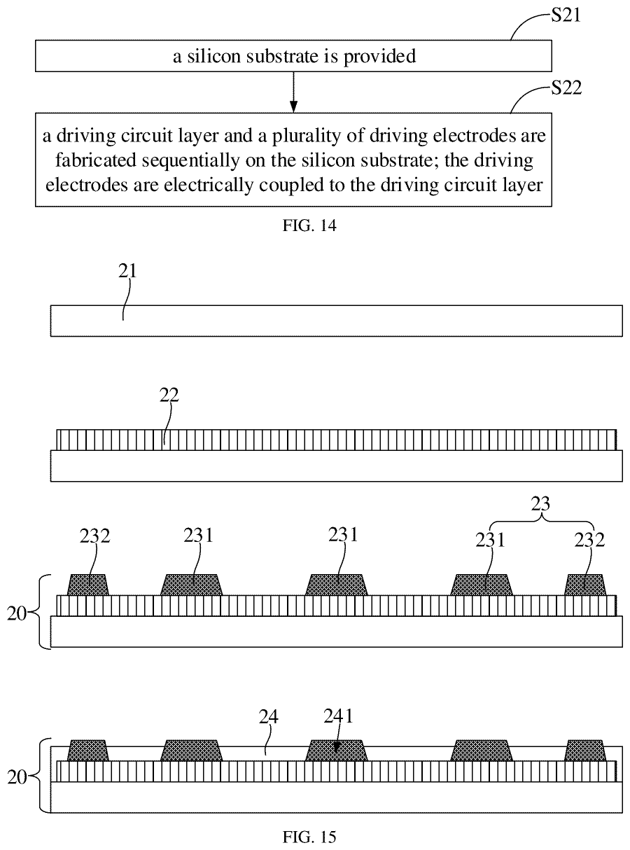

As shown in FIG. 14 and FIG. 15, FIG. 14 is a schematic flow chart of block S20 shown in FIG. 9, and FIG. 15 is a schematic process chart of a driving substrate shown in FIG. 14. The driving substrate 20 is manufactured by the following blocks.

At block S21, a silicon substrate 21 is provided.

At block S22, a driving circuit layer 22 and a plurality of driving electrodes 23 are fabricated sequentially on the silicon substrate 21. The driving electrodes 23 are electrically coupled to the driving circuit layer 22.

In some embodiments, block S23 may be included. At block S23, an insulating protective layer 24 is fabricated on the driving circuit layer 22, and a plurality of via-holes 241 are formed in the insulating protective layer 24 to expose the driving electrodes 23. The insulating protective layer 24 may include an organic insulating layer and/or an inorganic insulating layer. The insulating protective layer 24 may be configured as an inorganic insulating layer, and the inorganic insulating layer may be an inorganic insulating material such as silicon dioxide, silicon nitride, or silicon oxynitride. Block S23 may be operated after the driving electrodes 23 are fabricated, or may be operated before the driving electrodes 23 are fabricated after the driving circuit layer 22 is fabricated and formed, and may be arranged according to actual requirements.

The structure and function of the driving substrate 20 fabricated and formed by the above blocks are the same as or similar to the structure and function of the driving substrate 20 involved in the above embodiments, and may achieve the same technical effects. Please refer to the relevant descriptions above for details, and will not repeat here.

As shown in FIG. 1, after fabricating and forming the light-emitting substrate 10 and the driving substrate 20, through block S30, the cathode electrodes 15 of the light-emitting substrate 10 are electrically coupled to the cathode driving electrodes 232 of the driving substrate 20 through the corresponding bonding portions 16, and the anode electrodes 12 are electrically coupled to the anode driving electrodes 231 through the corresponding bonding portions 16, enabling the driving substrate 20 to drive the light-emitting units L to emit light and to display the image.

In embodiments of the present disclosure, a display device (not shown) is provided. The display device includes the display panel 100 described in the aforementioned embodiments. The display panel 100 may be manufactured by the manufacturing method introduced in the aforementioned embodiments.

The foregoing is only embodiments of the present disclosure, and does not limit the scope of the patent of the present disclosure. Any equivalent structural or equivalent process modifications made by using the contents of the description and drawings of the present disclosure, or directly or indirectly applied to other related technical fields, are similarly fall within the scope of patent protection of the present disclosure.

1. A light-emitting substrate, comprising:
a glass substrate, comprising a first side and a second side opposite to each other, wherein the glass substrate has a plurality of glass through-holes defined therein;
a plurality of light-emitting units, arranged on the first side of the glass substrate, each comprising an anode electrode, a light-emitting layer, and a cathode electrode stacked in sequence along a direction away from the glass substrate; wherein, the anode electrode covers a corresponding one of the glass through-holes, and comprises a light-condensing layer, a first reflective layer, a first transparent conductive layer, a second reflective layer, and a second transparent conductive layer, which are stacked in sequence along the direction away from the glass substrate; the light-condensing layer is configured to concentrate lasers located in a region of the corresponding one of the glass through-holes on the second side, the first reflective layer is configured to reflect the lasers, and the lasers are configured to form the corresponding one of the glass through-holes;
a plurality of bonding portions, arranged on the second side of the glass substrate, each passing through a corresponding one of the glass through-holes to be in contact with and electrically connected to the anode electrode or the cathode electrode; wherein the bonding portions are configured for alignment bonding with a driving substrate.

2. The light-emitting substrate according to claim 1, wherein materials of the first reflective layer and the second reflective layer comprise silver or aluminum, and a material of the light-condensing layer comprises copper, aluminum, or molybdenum.

3. The light-emitting substrate according to claim 1, further comprising a thermal insulation layer; wherein the thermal insulation layer has a plurality of hollowed-out portions defined therein, and the anode electrode is located in a corresponding one of the hollowed-out portions and extends out of the corresponding one of the hollowed-out portions, partially overlapping with the thermal insulation layer; an overlapping portion of the thermal insulation layer is located between the anode electrode and the glass substrate, and a width of the overlapping portion is not less than a first preset value; the thermal insulation layer is configured to block energy of the lasers, and the first preset value is a precision of a manufacturing process.

4. The light-emitting substrate according to claim 3, wherein an outer side of the thermal insulation layer away from the anode electrode extends beyond an edge of the light-emitting layer along a direction parallel to the glass substrate, a width of an excess portion of the thermal insulation layer is not less than a second preset value, and the second preset value is another precision of the manufacturing process.

5. The light-emitting substrate according to claim 3, wherein the thermal insulation layer covers the first side of the glass substrate entirely and has the hollowed-out portions defined therein.

6. The light-emitting substrate according to claim 3, wherein an orthographic projection of each of the hollowed-out portions projected on the glass substrate is coincident with a corresponding one of the glass through-holes along a direction perpendicular to the glass substrate; a thickness of the thermal insulation layer along the direction perpendicular to the glass substrate ranges from 0.5 μm to 2.0 μm; a material of the thermal insulation layer comprises a porous material or a vacuum thermal insulation material.

7. The light-emitting substrate according to claim 1, further comprising a thermal insulation layer arranged on the second side of the glass substrate; wherein the thermal insulation layer has a plurality of hollowed-out portions defined therein, each of the hollowed-out portions corresponds to and communicated with a corresponding one of the glass through-holes, and each of the boding portions passes through the each of the hollowed-out portions and the corresponding one of the glass through-holes.

8. The light-emitting substrate according to claim 7, wherein an orthographic projection of one of the hollowed-out portions projected on the glass substrate is located within an orthographic projection of the anode electrode projected on the glass substrate; an edge of the anode electrode overlaps with the thermal insulation layer along a direction perpendicular to the glass substrate.

9. The light-emitting substrate according to claim 1, wherein the corresponding one of the glass through-holes is located within a region of an orthographic projection of the anode electrode projected on the glass substrate.

10. The light-emitting substrate according to claim 1, wherein cathode electrodes of a part of the light-emitting units extend to the first side of the glass substrate, and a part of the bonding portions passes through corresponding glass through-holes to be in contact with and electrically connected to the cathode electrodes.

11. A manufacturing method of a display panel, comprising:
manufacturing a light-emitting substrate, comprising:
providing a glass substrate;
forming a plurality of anode electrodes on a first side of the glass substrate, comprising: depositing a light-condensing layer, a first reflective layer, a first transparent conductive layer, a second reflective layer, and a second transparent conductive layer sequentially, and performing a patterning process to form the anode electrodes;
depositing a plurality of light-emitting layers and a plurality of cathode electrodes sequentially on the anode electrodes to form a plurality of light-emitting units;
forming a plurality of glass through-holes on a second side of the glass substrate by laser ablation, a part of the glass through-holes being located within orthographic projections of the anode electrodes projected on the glass substrate; wherein, the light-condensing layer is configured to concentrate lasers, and the first reflective layer is configured to reflect the lasers;
depositing a metal layer on the second side of the glass substrate, enabling the metal layer to fill within the glass through-holes and to be in contact with and electrically connected to the anode electrodes and the cathode electrodes respectively, and performing a patterning process on the metal layer to form a plurality of bonding portions;
manufacturing a driving substrate, comprising:
providing a silicon substrate;
fabricating a driving circuit layer and a plurality of driving electrodes sequentially on the silicon substrate, wherein the driving electrodes are electrically coupled to the driving circuit layer;
aligning and bonding the bonding portions of the light-emitting substrate with the driving electrodes of the driving substrate.

12. The manufacturing method of the display panel according to claim 10, wherein before the forming a plurality of anode electrodes on a first side of the glass substrate, the manufacturing method further comprises:
forming a thermal insulation layer on the first side of the glass substrate; wherein the thermal insulation layer has a plurality of hollowed-out portions defined therein, each of the anode electrodes is formed in a corresponding one of the hollowed-out portions and extends to an upper surface of the thermal insulation layer, partially overlapping with the thermal insulation layer; a width of an overlapping portion of the thermal insulation layer overlapping with the each of the anode electrodes is not less than a first preset value, and the first preset value is a precision of a manufacturing process; a thickness of the thermal insulation layer along a direction perpendicular to the glass substrate ranges from 0.5 μm to 2.0 μm.

13. The manufacturing method of the display panel according to claim 12, wherein a material of the thermal insulation layer comprises a porous material or a vacuum thermal insulation material; in the forming a thermal insulation layer on the first side of the glass substrate, a patterned thermal insulation layer is formed by using 3D printing, inkjet printing, or a patterned template process.

14. The manufacturing method of the display panel according to claim 12, wherein in the forming a plurality of glass through-holes on a second side of the glass substrate by laser ablation, spots of the lasers on the second side of the glass substrate coincides with a corresponding one of the hollowed-out portions along the direction perpendicular to the glass substrate, so that one of the glass through-holes is coincident with the corresponding one of the hollowed-out portions along the direction perpendicular to the glass substrate.

15. A display panel, comprising:
a light-emitting substrate, comprising:
a glass substrate, comprising a first side and a second side opposite to each other, wherein the glass substrate has a plurality of glass through-holes defined therein;
a plurality of light-emitting units, arranged on the first side of the glass substrate, each comprising an anode electrode, a light-emitting layer, and a cathode electrode stacked in sequence along a direction away from the glass substrate; wherein, the anode electrode covers a corresponding one of the glass through-holes, and comprises a light-condensing layer, a first reflective layer, a first transparent conductive layer, a second reflective layer, and a second transparent conductive layer, which are stacked in sequence along the direction away from the glass substrate; the light-condensing layer is configured to concentrate lasers located in a region of the corresponding one of the glass through-holes on the second side, the first reflective layer is configured to reflect the lasers, and the lasers are configured to form the corresponding one of the glass through-holes;
a plurality of bonding portions, arranged on the second side of the glass substrate, each passing through a corresponding one of the glass through-holes to be in contact with and electrically connected to the anode electrode or the cathode electrode;
a driving substrate, aligned and bonded with the bonding portions of the light-emitting substrate for driving the light-emitting substrate to emit light.

16. The display panel according to claim 15, wherein materials of the first reflective layer and the second reflective layer comprise silver or aluminum, and a material of the light-condensing layer comprises copper, aluminum, or molybdenum.

17. The display panel according to claim 15, wherein the light-emitting substrate further comprises a thermal insulation layer; the thermal insulation layer has a plurality of hollowed-out portions defined therein, and the anode electrode is located in a corresponding one of the hollowed-out portions and extends out of the corresponding one of the hollowed-out portions, partially overlapping with the thermal insulation layer; an overlapping portion of the thermal insulation layer is located between the anode electrode and the glass substrate, and a width of the overlapping portion is not less than a first preset value; the thermal insulation layer is configured to block energy of the lasers, and the first preset value is a precision of a manufacturing process.

18. The display panel according to claim 17, wherein an outer side of the thermal insulation layer away from the anode electrode extends beyond an edge of the light-emitting layer along a direction parallel to the glass substrate, a width of an excess portion of the thermal insulation layer is not less than a second preset value, and the second preset value is another precision of the manufacturing process.

19. The display panel according to claim 17, wherein the thermal insulation layer covers the first side of the glass substrate entirely and has the hollowed-out portions defined therein.

20. The display panel according to claim 17, wherein an orthographic projection of each of the hollowed-out portions projected on the glass substrate is coincident with a corresponding one of the glass through-holes along a direction perpendicular to the glass substrate; a thickness of the thermal insulation layer along the direction perpendicular to the glass substrate ranges from 0.5 μm to 2.0 μm; a material of the thermal insulation layer comprises a porous material or a vacuum thermal insulation material.
